(19) United States
(12) Patent Application Publication
(10) Pub. No.: US 2008/0088352 A1
(43) Pub. Date: Apr. 17, 2008

(54) Level shift circuit

(75) Inventor: Yu-Jui Chang, Tainan County (TW)

Correspondence Address: J C PATENTS, INC., 4 VENTURE, SUITE 250, IRVINE, CA, 92618, US

(73) Assignee: HIMAX TECHNOLOGIES LIMITED, Tainan County (TW)

(21) Appl. No.: 11/548,953

(22) Filed: Oct. 12, 2006

(51) Int. Cl. H03L 5/00

(52) U.S. Cl. 327/333

(57) ABSTRACT

A level shift circuit for conversion of a low-voltage input signal into a high-voltage output signal is provided. The level shift circuit includes: two pairs of transistors, a control unit, and a charge-sharing unit. The transistors in one of the pairs are both turned on in response to the input signal so that a voltage on a reference voltage node is coupled to a gate of one of the transistors in the other pair. A control unit decouples and couples a first reference voltage from the reference voltage node during a first and second phases respectively. A charge-sharing unit is temporarily shorting for preventing failure of conversion.

### BACKGROUND OF THE INVENTION

1. Field of Invention

The present invention relates to a level shift circuit, and more particularly to a level shift circuit in a source driver of LCD.

2. Description of Related Art

FIG. 1 is a circuit diagram of a conventional level shift circuit 100. The level shift 100 includes a plurality of transistors 101˜105. A low-voltage signal IN1 is inputted to the gate of the transistor 104 and an inverted low-voltage signal INB1 is inputted to the gate of the transistor 105. The transistor 104 and the transistor 105 are electrically connected to the transistor 102 and the transistor 103, respectively. The transistor 102 and the transistor 103 are cross-coupled to each other and are formed similar as clamping transistors. A control signal CTRL0 is inputted to a gate of the transistor 101. A voltage VDDA is coupled to the transistor 101 and a voltage VSSA is coupled the transistors 104,105. The transistors 102,103 are commonly coupled to a node n1. The node n1 includes voltage V1. The transistor 103 outputs a high-voltage signal OD51 and the transistor 102 outputs an inverted high-voltage signal ODB51.

FIG. 2 shows the signals in the level shift circuit 100 upon transition of the input signal IN1 from a high logic state to a low logic state. The transition starts from the time T21. At time T21, the control signal CTRL0 goes high to turn off the transistor 101 so that the voltage V1 drops. The transistor 102 is turned on and couples the voltage V1 to its drain. Since the voltage level of the signal ODB51 should be high enough to turn off the transistor 103, the control signal CTRL0 slightly drops at time T22 to partially turn on the transistor 101 so that the levels of the voltage V1 and signal ODB51 start to rise at time T22. However, the level of the signal ODB51 will not rise to a level high enough to fully turn off the transistor 103 at the end of the transition (at time T23) if the level of the input signal IN1 is too low. For such a low input signal, when the control signal CTRL0 turns on the transistor 101, the partially turned on transistor 103 couples a high voltage to its drain, which turns off the transistor 102 and keeps the signal ODB51 staying at a relatively low level. Thus, the transistor 103 is turned on and the signal OD51 is pulled high, which means that the transition fails.

### SUMMARY OF THE INVENTION

An objective of the present invention is to provide a level shift circuit for conversion of a low-voltage input signal into a high-voltage output signal, which prevents failure of transition due to low input voltage.

Another object of the present invention is to provide a method for conversion of a low-voltage input signal into a high-voltage output signal, which prevents failure of transition due to low input voltage.

The present invention provides a level shift circuit for conversion of a low-voltage input signal into a high-voltage output signal, the level shift circuit includes: two pairs of transistors, a control unit, and a charge-sharing unit. The transistors in one of the pairs are both turned on in response to the input signal so that a voltage on a reference voltage node is coupled to a gate of one of the transistors in the other pair. The control unit decouples and couples a first reference voltage from the reference voltage node during a first and second phases respectively. The charge-sharing unit couples a second reference voltage to the gate of the transistor, to which the voltage on the reference voltage node is coupled, during at least a part of the first phase.

The present invention further provides a method of for conversion of a low-voltage input signal into a high-voltage output signal using at least two pairs of transistors wherein the transistors in one of the pairs are both turned on in response to the input signal so that a voltage on a reference voltage node is coupled to a gate of one of the transistors in the other pair. The method comprises the steps of: decoupling and coupling a first reference voltage from the reference voltage node during a first and second phases respectively; and coupling a second reference voltage to the gate of the transistor, to which the voltage on the reference voltage node is coupled, during at least a part of the first phase.

In the present invention, as the charge-sharing is arranged in the level shift circuit. The charge-sharing is temporarily shorting for preventing failure of transition.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification.

FIG. 1 is a circuit diagram of a conventional level shift circuit 100.

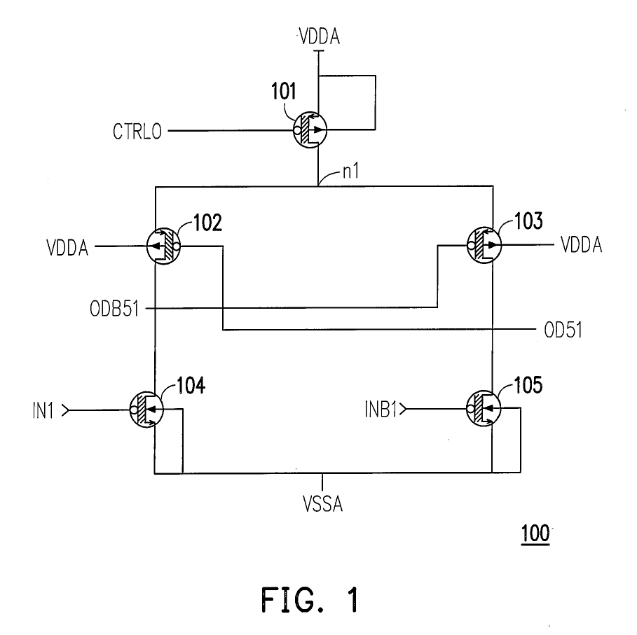

FIG. 2 is a timing diagram of the level shift circuit 100 illustrated in FIG. 1.

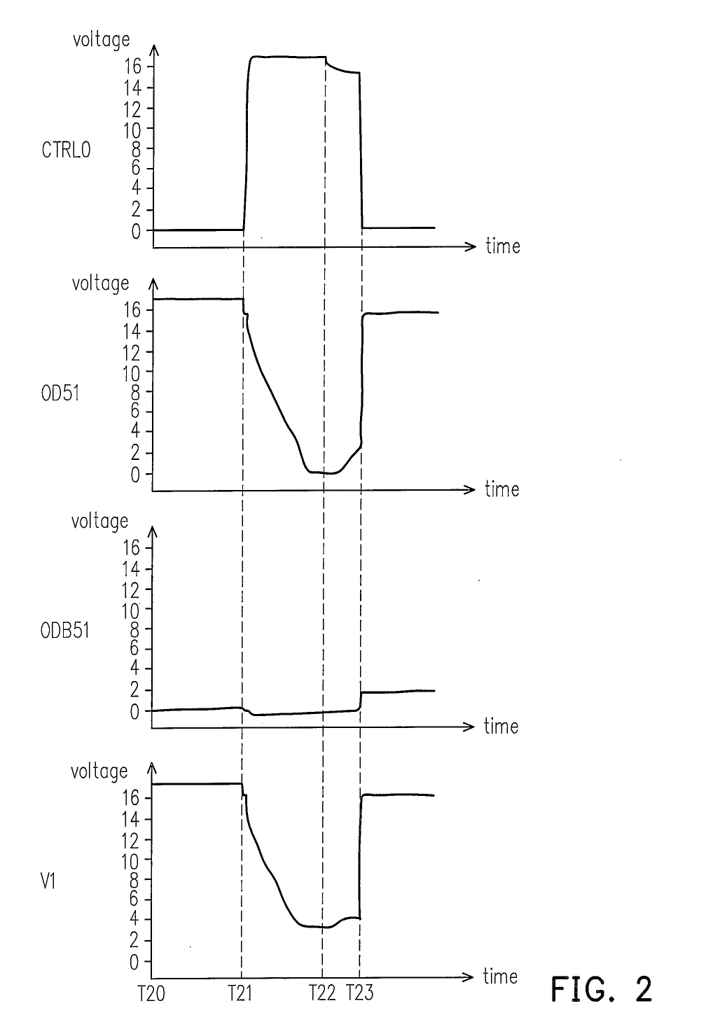

FIG. 3 is a circuit diagram of a level shift circuit 300 according to the embodiment of the present invention.

FIG. 4 is a timing diagram of the level shift circuit 300 according to the embodiment of the present invention.

### DESCRIPTION OF EMBODIMENTS

The present invention will now be described with reference to the accompanying drawings, in which exemplary embodiments of the invention are shown. The invention may, however, be embodied in many different forms and should not be construed as being limited to the embodiments set forth herein. In the drawings, whenever the same element reappears in subsequent drawings, it is denoted by the same reference numeral.

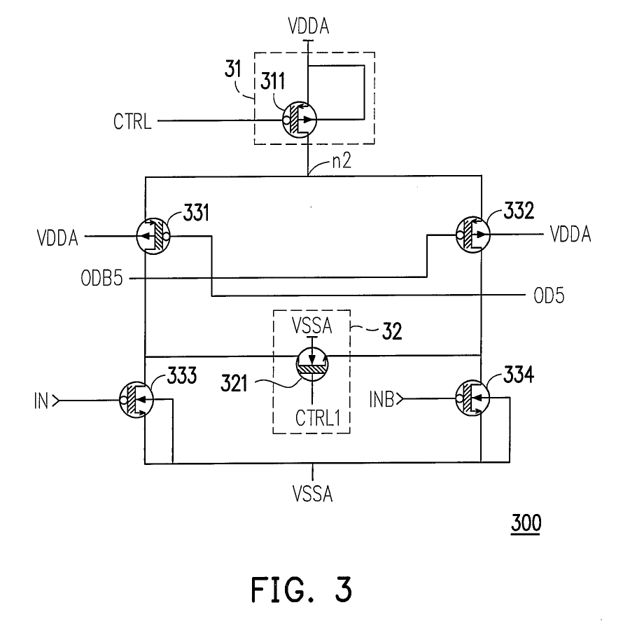

FIG. 3 is a circuit diagram of a level shift circuit 300 according to the embodiment of the present invention. The level shift circuit 300 converts a low-voltage input signal into a high-voltage output signal. For instance, a low-voltage input signal refers to a signal having a dynamic range from 0 volt to 2.3 volts while a high-voltage output signal refers to a signal having a dynamic range from 0 volt to 20 volts. Those skilled in the art should understand that the dynamic ranges of the low-voltage input signal and the high-voltage output signal are not limited to those described above.

The level shift circuit includes: a control unit 31, a charge-sharing unit 32, a first pair of transistors 331 and 334, and a second pair of transistors 332 and 333. The control unit 31 includes a transistor 311. The charge-sharing unit includes a transistor 321. The transistors 311,331,332 are PMOS transistors, and the transistors 321,333,334 are NMOS transistors. The transistors in the first or second pair are both turned on in response to the input signal IN so that a voltage on a reference voltage node n2 is coupled to a gate of the upper transistor 331 or 332 in the other pair. More specifically, when the state of the low-voltage input signal IN is high and the inverted low-voltage input signal INB is low, the transistors 332, 333 are both turned on so that a voltage V2 on the reference voltage node n2 is coupled to the gate of the transistor 331. When the state of the low-voltage input signal IN is low and the inverted low-voltage signal INB is high, the transistors 331, 334 are both turned on so that the voltage V2 on the reference voltage node n2 is coupled to the gate of the transistors 332.

The transistor 311 has a source electrically connected to a reference voltage VDDA, a gate for receiving the control signal CTRL, and a drain electrically connected to the reference voltage node n2. A source of the transistor 331 and a source of the transistor 332 are electrically connected to the drain of the transistor 311, a gate of the transistor 331 is electrically connected to a drain of the transistor 332, and a gate of the transistor 332 is electrically connected to a drain of the transistor 331. A source of the transistor 333 and a source of the transistor 334 are electrically connected to the reference voltage VSSA. A drain of the transistor 333 is electrically connected to the drain of the transistor 331. A drain of the transistor 334 is electrically connected to the drain of the transistor 332. The transistor 321 acts as a switch. The transistor 321 has a first source/drain terminal electrically connected to the drain of the transistor 333 and has a second source/drain terminal electrically connected to the drain of the transistor 334, and controlled by a control signal CTRL1 received at the gate.

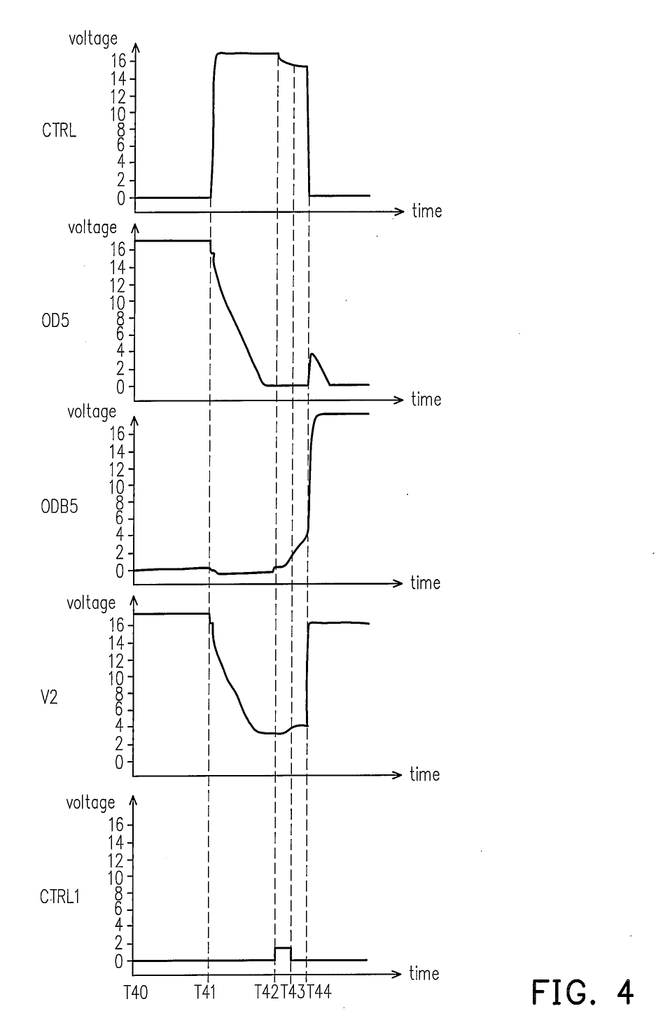

FIG. 4 shows the signals in the level shift circuit 300 upon the transition of the input signal IN from a high logic state to a low logic state. The transition starts from the time T41. The control unit 31 decouples the reference voltage VDDA from the reference voltage node n2 in response to a high logic state of the signal CTRL during a transition phase from time T41 to T44, and couples the reference voltage VDDA to the reference voltage node n2 in response to a low logic state of the signal CTRL during a driving phase beyond the transition phase. The control signal CTRL slightly drops at time T42 to partially turn on the transistor 311. Further, in response to the high and low logic state of the signal CTRL1, the charge-sharing unit 32 couples and decouples the drains of the transistors 334,335 during and beyond a duration from time T42 to T43, respectively. For the transition of the input signal IN from the high logic state to the low logic state, the charge-sharing unit 32 couples the reference voltage VSSA to the gate of the transistor 332 from time T42 to T43 since the transistor 331 is turned on and couples the voltage V2 on the reference voltage node n2 to its drain. The charge-sharing unit 32 decouples the reference voltage VSSA to the gate of the transistor 332 in response to a low logic state of the signal CTRL beyond the duration from time T42 to T43. Thus, the level of the signal ODB5 rises in the duration from time T42 to T43.

Since the coupling of the drains of the transistors 331 and 332 helps to increase the voltage on the gate of the to-be-turned-off transistor 332 or 331, the level shift circuit 300 can sustain an input signal having a lower level than the conventional one does.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A level shift circuit for conversion of a low-voltage input signal into a high-voltage output signal, the circuit comprising:
two pairs of transistors, wherein the transistors in one of the pairs are both turned on in response to the input signal so that a voltage on a reference voltage node is coupled to a gate of one of the transistors in the other pair;
a control unit decoupling and coupling a first reference voltage from the reference voltage node during a first and second phases respectively; and
a charge-sharing unit coupling a second reference voltage to the gate of the transistor, to which the voltage on the reference voltage node is coupled, during at least a part of the first phase.

2. The level shift circuit as claimed in claim 1, wherein the control unit comprises:
a first transistor having a source electrically connected to the first reference voltage, a gate for receiving a first control signal, and a drain electrically connected to the reference voltage node;
wherein the first control signal has a first and second levels during the first and second phases so that the first transistor is turned off and on during the first and second phases, respectively.

3. The level shift circuit as claimed in claim 2, wherein the transistors comprises:
a second transistor and a third transistor, wherein a source of the second transistor and a source of the third transistor are electrically connected to the drain of the first transistor, a gate of the second transistor is electrically connected to a drain of the third transistor, and a gate of the third transistor is electrically connected to a drain of the second transistor; and
a fourth transistor and a fifth transistor, wherein a source of the fourth transistor and a source of the fifth transistor are electrically connected to the second reference voltage, a drain of the fourth transistor is electrically connected to the drain of the second transistor, a drain of the fifth transistor is electrically connected to the drain of the third transistor.

4. The level shift circuit as claimed in claim 3, wherein the charge-sharing unit comprises:
a switch having a first terminal of the switch electrically connected to the drain of the fourth transistor and a second terminal electrically connected to the drain of the fifth transistor, and controlled by a second control signal;
wherein the second control signal has a third and fourth levels during and beyond the part of the first phase so that the drains of the fourth and fifth transistors are coupled and decoupled during and beyond the part of the first phase, respectively.

5. The level shift circuit as claimed in claim 4, wherein the switch, and the fourth and fifth transistors are NMOS transistors, and the first, second and third transistors are PMOS transistors.

6. The level shift circuit as claimed in claim 4, wherein the first reference voltage is higher than the second reference voltage.

7. A method for conversion of a low-voltage input signal into a high-voltage output signal using at least two pairs of transistors wherein the transistors in one of the pairs are both turned on in response to the input signal so that a voltage on a reference voltage node is coupled to a gate of one of the transistors in the other pair, the method comprising the steps of:
decoupling and coupling a first reference voltage from the reference voltage node during a first and second phases respectively; and
coupling a second reference voltage to the gate of the transistor, to which the voltage on the reference voltage node is coupled, during at least a part of the first phase.

8. The method as claimed in claim 7, further comprising using a control unit to decouple and to couple the first reference voltage from the reference voltage node during the first and second phases respectively, wherein the control unit comprises:
a first transistor having a source electrically connected to the first reference voltage, a gate for receiving a first control signal, and a drain electrically connected to the reference voltage node;
wherein the first control signal has a first and second levels during the first and second phases so that the first transistor is turned off and on during the first and second phases, respectively.

9. The method as claimed in claim 8, wherein the transistors comprises:
a second transistor and a third transistor, wherein a source of the second transistor and a source of the third transistor are electrically connected to the drain of the first transistor, a gate of the second transistor is electrically connected to a drain of the third transistor, and a gate of the third transistor is electrically connected to a drain of the second transistor; and
a fourth transistor and a fifth transistor, wherein a source of the fourth transistor and a source of the fifth transistor are electrically connected to the second reference voltage, a drain of the fourth transistor is electrically connected to the drain of the second transistor, a drain of the fifth transistor is electrically connected to the drain of the third transistor.

10. The method as claimed in claim 9, further comprising using a charge-sharing unit to couple the second reference voltage to the gate of the transistor, to which the voltage on the reference voltage node is coupled, during at least a part of the first phase, wherein the charge-sharing unit comprises:
a switch having a first terminal of the switch electrically connected to the drain of the fourth transistor and a second terminal electrically connected to the drain of the fifth transistor, and controlled by a second control signal;
wherein the second control signal has a third and fourth levels during and beyond the part of the first phase so that the drains of the fourth and fifth transistors are coupled and decoupled during and beyond the part of the first phase, respectively.

11. The method as claimed in claim 10, wherein the switch, and the fourth and fifth transistors are NMOS transistors, and the first, second and third transistors are PMOS transistors.

12. The method as claimed in claim 10, wherein the first reference voltage is higher than the second reference voltage.
